(19) United States
(12) Patent Application Publication
(10) Pub. No.: US 2025/0344000 A1
(43) Pub. Date: Nov. 6, 2025

(54) SOLID-STATE IMAGING DEVICE AND IMAGING APPARATUS

(71) Applicant: Nuvoton Technology Corporation Japan, Kyoto (JP)

(72) Inventors: Masaru KATO, Kyoto (JP); Makoto IKUMA, Kyoto (JP); Osamu SARUWATARI, Kyoto (JP); Kazutoshi ONOZAWA, Kyoto (JP); Toru YAMADA, Kyoto (JP)

(21) Appl. No.: 19/273,625

(22) Filed: Jul. 18, 2025

Related U.S. Application Data
(63) Continuation of application No. PCT/JP2024/002491, filed on Jan. 26, 2024.
(60) Provisional application No. 63/442,311, filed on Jan. 31, 2023.
(60) Provisional application No. 63/442,317, filed on Jan. 31, 2023.

(51) Int. Cl. H04N 25/59; H04N 25/63; H04N 25/771; H04N 25/78

(52) U.S. Cl. CPC H04N 25/59; H04N 25/771; H04N 25/78; H04N 25/63

(57) ABSTRACT

A solid-state imaging device includes: a pixel array in which a plurality of pixels are arranged in rows and columns; and a first power supply line. Each of the plurality of pixels includes a photoelectric converter, a floating diffusion, a capacitance accumulator, a first transfer transistor, an overflow transistor, a second transfer transistor, a first reset transistor, and an amplifier transistor. The solid-state imaging device further includes a resetter for resetting the floating diffusion and the capacitance accumulator at voltages different from each other.

### CROSS REFERENCE TO RELATED APPLICATIONS

This is a continuation application of PCT International Patent Application No. PCT/JP2024/002491 filed on Jan. 26, 2024, designating the United States of America, which is based on and claims priority of U.S. Provisional Patent Application No. 63/442,311 filed on Jan. 31, 2023 and U.S. Provisional Patent Application No. 63/442,317 filed on Jan. 31, 2023. The entire disclosures of the above-identified applications, including the specifications, drawings and claims are incorporated herein by reference in their entirety.

### FIELD

The present disclosure relates to a solid-state imaging device and an imaging apparatus including the solid-state imaging device.

### BACKGROUND

Solid-state imaging devices for capturing images are known.

### CITATION LIST

### Patent Literature

PTL 1: Japanese Patent No. 4497366
PTL 2: Japanese Unexamined Patent Application Publication No. 2010-068433
PTL 3: Japanese Patent No. 5521862

### SUMMARY

### Technical Problem

Conventionally, for example, as described in Patent Literature (PTL) 1, a solid-state imaging device that includes storage capacitors in pixels and is intended to increase saturation has been known as one of techniques for achieving high dynamic range (HDR).

In order to achieve wider dynamic range, it is necessary to improve an S/N ratio, that is, not only to increase the amount of saturation charge but also to achieve both an increase in the amount of saturation charge and a reduction of noise.

In view of this, the present disclosure has an object to provide, for example, a solid-state imaging device that makes it possible to achieve both an increase in the amount of saturation charge and a reduction of readout noise generated when a signal charge accumulated in a capacitance accumulator is read out.

### Solution to Problem

A solid-state imaging device according to one aspect of the present disclosure is a solid-state imaging device comprising: a pixel array in which a plurality of pixels are arranged in rows and columns; and a first power supply line, wherein each of the plurality of pixels includes: a photoelectric converter that converts received light into a signal charge; a floating diffusion for accumulating the signal charge; a capacitance accumulator for accumulating the signal charge; a first transfer transistor for reading out the signal charge from the photoelectric converter to the floating diffusion; an overflow transistor for discharging, to the capacitance accumulator, the signal charge that overflows from the photoelectric converter; a second transfer transistor for transferring the signal charge accumulated in the capacitance accumulator to the floating diffusion; a first reset transistor that includes a first terminal connected to the second transfer transistor and a second terminal connected to the first power supply line; and an amplifier transistor that includes a gate connected to the floating diffusion, the solid-state imaging device further comprises a resetter for resetting the floating diffusion and the capacitance accumulator at voltages different from each other.

A solid-state imaging device according to one aspect of the present disclosure is a solid-state imaging device comprising: a pixel array in which a plurality of pixels are arranged in rows and columns; and a power supply line, wherein each of the plurality of pixels includes: a photoelectric converter that converts received light into a signal charge; a first floating diffusion for accumulating the signal charge; a second floating diffusion for accumulating the signal charge; a capacitance accumulator for accumulating the signal charge; a first transfer transistor for reading out the signal charge from the photoelectric converter to the first floating diffusion; an overflow transistor for discharging, to the capacitance accumulator, the signal charge that overflows from the photoelectric converter; a second transfer transistor for transferring the signal charge accumulated in the capacitance accumulator to the second floating diffusion; a reset transistor that includes a first terminal connected to the second transfer transistor and a second terminal connected to the power supply line; a third transfer transistor that includes a third terminal connected to the first floating diffusion and a fourth terminal connected to the second floating diffusion; a fourth transfer transistor that includes a fifth terminal connected to the second floating diffusion and a sixth terminal connected to the reset transistor; and an amplifier transistor that includes a gate connected to the first floating diffusion, the solid-state imaging device further comprises a vertical scanning circuit that puts the fourth transfer transistor of each of the plurality of pixels into a non-conductive state, the reset transistor of the pixel into the non-conductive state, and the second transfer transistor of the pixel into a conductive state.

An imaging apparatus according to one aspect of the present disclosure includes the above-described solid-state imaging device.

### Advantageous Effects

The solid-state imaging device etc. according to one aspect of the present disclosure makes it possible to achieve both an increase in the amount of saturation charge and a reduction of readout noise generated when a signal charge accumulated in a capacitance accumulator is read out.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a block diagram illustrating the configuration of a solid-state imaging device according to Embodiment 1.

FIG. 2 is a circuit diagram illustrating the configuration of a pixel according to Embodiment 1.

FIG. 3 is a schematic diagram illustrating a state in which the solid-state imaging device according to Embodiment 1 resets a capacitance accumulator.

FIG. 4 is a schematic diagram illustrating a state in which the solid-state imaging device according to Embodiment 1 resets a floating diffusion.

FIG. 5 is a graph showing a state in which the solid-state imaging device according to Embodiment 1 achieves both an increase in the amount of saturation charge and a reduction of readout noise generated when an electric charge accumulated in the capacitance accumulator is read out.

FIG. 6 is a block diagram illustrating the configuration of a solid-state imaging device according to Embodiment 2.

FIG. 7 is a circuit diagram illustrating the configuration of a pixel according to Embodiment 2.

FIG. 8 is a schematic diagram illustrating a state in which the solid-state imaging device according to Embodiment 2 resets a capacitance accumulator.

FIG. 9 is a schematic diagram illustrating a state in which the solid-state imaging device according to Embodiment 2 resets a floating diffusion.

FIG. 10 is a block diagram illustrating the configuration of a solid-state imaging device according to Embodiment 3.

FIG. 11 is a circuit diagram illustrating the configuration of a pixel according to Embodiment 3.

FIG. 12 is a schematic diagram illustrating a state in which the solid-state imaging device according to Embodiment 3 resets a capacitance accumulator.

FIG. 13 is a schematic diagram illustrating a state in which the solid-state imaging device according to Embodiment 3 resets a floating diffusion.

FIG. 14 is a block diagram illustrating the configuration of a solid-state imaging device according to Embodiment 4.

FIG. 15 is a circuit diagram illustrating the configuration of a pixel according to Embodiment 4.

FIG. 16 is a schematic diagram illustrating a state in which the solid-state imaging device according to Embodiment 4 transfers a signal charge from a photoelectric converter to a second floating diffusion.

FIG. 17 is a schematic diagram illustrating a state in which each of transistors included in the pixel according to Embodiment 4 is driven by a corresponding one of control signals outputted from a vertical scanning circuit according to Embodiment 4.

FIG. 18 is an example of a timing chart for control signals used when the vertical scanning circuit according to Embodiment 4 drives the pixel according to Embodiment 4.

FIG. 19 is a schematic diagram illustrating a potential of each of constituent elements of the pixel according to Embodiment 4.

FIG. 20 is a block diagram illustrating the configuration of an imaging apparatus according to Embodiment 5.

### DESCRIPTION OF EMBODIMENTS

### Circumstances Leading to One Aspect of the Present Disclosure

To increase the amount of saturation charge, it is effective to increase a voltage at which a floating diffusion is reset.

Moreover, in order to completely discharge a signal charge accumulated in a capacitance accumulator, that is, in order to reduce readout noise such as a residual image generated when the signal charge accumulated in the capacitance accumulator is read out, it is effective to cause a voltage applied to the gate of a transfer transistor that transfers the signal charge accumulated in the capacitance accumulator to be at least a voltage obtained by adding a threshold voltage of the transfer transistor to a voltage at which the capacitance accumulator is reset. Furthermore, in order to reduce dark current noise that occurs in the transfer transistor at the time of exposure, it is also effective to accumulate holes in an interface of the transfer transistor by applying a negative voltage to the gate of the transfer transistor.

However, in order to ensure the reliability of the transfer transistor, it is necessary to keep the voltage applied to the gate of the transfer transistor within a specific voltage (hereinafter also referred to as a “reliability ensuring voltage”).

On the other hand, in conventional solid-state imaging devices, a floating diffusion and a capacitance accumulator are configured to be reset at the same voltage.

For this reason, the conventional solid-state imaging devices having the single reset voltage have a limitation in achieving both a further increase in the amount of saturation charge and a further reduction of noise generated at the time of performing readout from a storage capacitor.

The inventors repeatedly conducted intensive experiments and studies in order to solve this problem. As a result, the inventors gained knowledge that the problem can be solved by successfully causing a voltage at which a floating diffusion is reset and a voltage at which a capacitance accumulator is reset to be voltages different from each other.

Additionally, the inventors repeatedly conducted further experiments and studies, based on this knowledge. As a result, the inventors arrived at a solid-state imaging device etc. according to the present disclosure.

A solid-state imaging device according to one aspect of the present disclosure is a solid-state imaging device including: a pixel array in which a plurality of pixels are arranged in rows and columns; and a first power supply line. Each of the plurality of pixels includes: a photoelectric converter that converts received light into a signal charge; a floating diffusion for accumulating the signal charge; a capacitance accumulator for accumulating the signal charge; a first transfer transistor for reading out the signal charge from the photoelectric converter to the floating diffusion; an overflow transistor for discharging, to the capacitance accumulator, the signal charge that overflows from the photoelectric converter; a second transfer transistor for transferring the signal charge accumulated in the capacitance accumulator to the floating diffusion; a first reset transistor that includes a first terminal connected to the second transfer transistor and a second terminal connected to the first power supply line; and an amplifier transistor that includes a gate connected to the floating diffusion. The solid-state imaging device further includes a resetter for resetting the floating diffusion and the capacitance accumulator at voltages different from each other.

The solid-state imaging device thus configured makes it possible to reset the floating diffusion and the capacitance accumulator at the voltages different from each other.

For this reason, the solid-state imaging device thus configured makes it possible to both cause the voltage at which the floating diffusion is reset to be higher than a reliability ensuring voltage of the second transfer transistor, and cause the voltage at which the capacitance accumulator is reset to be lower than or equal to a voltage obtained by subtracting a threshold voltage of the second transfer transistor from the reliability ensuring voltage of the second transfer transistor.

Accordingly, the solid-state imaging device thus configured makes it possible to achieve an increase in the amount of saturation charge and a reduction of readout noise generated when a signal charge accumulated in the capacitance accumulator is read out.

Moreover, the resetter may include: a second power supply line that is included in the solid-state imaging device; and a second reset transistor that is included in each of the plurality of pixels and includes a third terminal connected to the second transfer transistor and a fourth terminal connected to the second power supply line.

Furthermore, a first voltage of the first power supply line may be lower than a second voltage of the second power supply line.

Moreover, a voltage at which the capacitance accumulator is reset may be the first voltage, and a voltage at which the floating diffusion is reset may be the second voltage.

Furthermore, the resetter may include a voltage booster for boosting a voltage of the floating diffusion, the voltage booster being included in the solid-state imaging device.

Moreover, the resetter may include a voltage switch that switches a voltage of the first power supply line alternatively between a first voltage and a second voltage different from the first voltage, the voltage switch being included in the solid-state imaging device.

Furthermore, the first voltage of the first power supply line may be lower than the second voltage.

Moreover, a voltage at which the capacitance accumulator is reset may be the first voltage, and a voltage at which the floating diffusion is reset may be the second voltage.

A solid-state imaging device according to one aspect of the present disclosure is a solid-state imaging device including: a pixel array in which a plurality of pixels are arranged in rows and columns; and a power supply line. Each of the plurality of pixels includes: a photoelectric converter that converts received light into a signal charge; a first floating diffusion for accumulating the signal charge; a second floating diffusion for accumulating the signal charge; a capacitance accumulator for accumulating the signal charge; a first transfer transistor for reading out the signal charge from the photoelectric converter to the first floating diffusion; an overflow transistor for discharging, to the capacitance accumulator, the signal charge that overflows from the photoelectric converter; a second transfer transistor for transferring the signal charge accumulated in the capacitance accumulator to the second floating diffusion; a reset transistor that includes a first terminal connected to the second transfer transistor and a second terminal connected to the power supply line; a third transfer transistor that includes a third terminal connected to the first floating diffusion and a fourth terminal connected to the second floating diffusion; a fourth transfer transistor that includes a fifth terminal connected to the second floating diffusion and a sixth terminal connected to the reset transistor; and an amplifier transistor that includes a gate connected to the first floating diffusion. The solid-state imaging device further comprises a vertical scanning circuit that puts the fourth transfer transistor of each of the plurality of pixels into a non-conductive state, the reset transistor of the pixel into the non-conductive state, and the second transfer transistor of the pixel into a conductive state.

The solid-state imaging device thus configured makes it possible to accumulate, in the capacitance accumulator via the second transfer transistor in the conductive state, a signal charge that overflows from the second floating diffusion via the third transfer transistor in the non-conductive state.

For this reason, it is possible to reduce the outflow of the signal charge overflowing from the second floating diffusion via the third transfer transistor in the non-conductive state to the power supply line, that is, electric charge loss.

Accordingly, the solid-state imaging device thus configured makes it possible to achieve both a further increase in the amount of saturation charge due to the reduction of the electric charge loss, and a reduction of readout noise generated when a signal charge accumulated in the capacitance accumulator is read out.

An imaging apparatus according to one aspect of the present disclosure includes the above-described solid-state imaging device.

As with the solid-state imaging device according to one aspect of the present disclosure, the imaging apparatus thus configured makes it possible to achieve both an increase in the amount of saturation charge and a reduction of readout noise generated when a signal charge accumulated in the capacitance accumulator is read out.

Hereinafter, specific examples of the solid-state imaging device etc. according to one aspect of the present disclosure are described with reference to the Drawings. Embodiments indicated below each show a different one of the specific examples of the present disclosure. As such, the numerical values, shapes, constituent elements, arrangements and connection states of constituent elements, steps (processes), orders of steps, etc. indicated in the following embodiments are mere examples, and are not intended to limit the present disclosure. In addition, the respective figures are schematic diagrams and are not necessarily precise illustrations. The same reference signs are assigned to substantially identical elements in each figure, and overlapping descriptions thereof are omitted or simplified.

### Embodiment 1

### Configuration

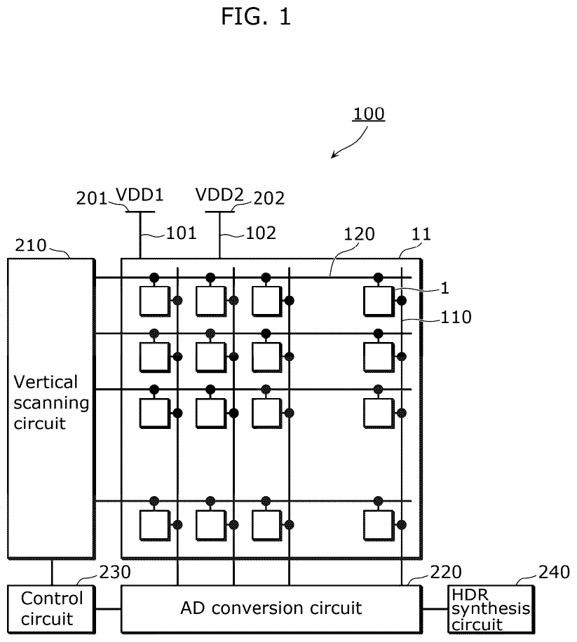

FIG. 1 is a block diagram illustrating the configuration of solid-state imaging device 100 according to Embodiment 3.

As shown in FIG. 1, solid-state imaging device 100 includes pixel array 11, vertical scanning circuit 210, AD conversion circuit 220, control circuit 230, HDR synthesis circuit 240, first power source 201, second power source 202, first power supply line 101, and second power supply line 102.

It should be noted that although the following description is based on a premise that solid-state imaging device 100 includes HDR synthesis circuit 240, solid-state imaging device 100 need not be configured to include HDR synthesis circuit 240. For example, an external device of solid-state imaging device 100 may be configured to include HDR synthesis circuit 240.

Pixel array 11 is configured by arranging a plurality of pixels 1 in m (m is an integer greater than or equal to 2) rows and n (n is an integer greater than or equal to 2) columns.

Pixel array 11 further includes: n vertical signal lines 110 that extend in the column direction and each of which is connected to m pixels 1 arranged in the column direction; and m control signal line groups 120 that extend in the row direction and each of which is connected to n pixels 1 arranged in the row direction.

Here, each of n vertical signal lines 110 is one signal line, whereas each of m control signal line groups 120 includes a plurality of signal lines.

It should be noted that although the following description is based on a premise that each of n vertical signal lines 110 is one signal line, each of n vertical signal lines 110 need not be configured as one signal line. For example, each of n vertical signal lines 110 may include a plurality of signal lines.

Vertical scanning circuit 210 drives each pixel 1 of pixel array 11 per row via m control signal line groups 120.

AD conversion circuit 220 converts n analog pixel signals outputted from n pixels 1 per row via n vertical signal lines 110 into n digital pixel signals. Next, AD conversion circuit 220 outputs the n digital pixel signals after AD conversion to HDR synthesis circuit 240.

It should be noted that AD conversion is performed in combination with correlated dual sampling that removes reset noise etc. at the time of a readout operation by calculating a difference between a result of AD conversion of pixel signals read out from pixels 1 in a reset state and a result of AD conversion of pixel signals read out from pixels 1 after exposure.

HDR synthesis circuit 240 generates an image by performing HDR synthesis on pixel signals outputted from AD conversion circuit 220.

First power source 201 is a power source that supplies power supply voltage VDD1.

Second power source 202 is a power source that supplies power supply voltage VDD2. In the present embodiment, the following description is based on a premise that power supply voltage VDD2 is higher than power supply voltage VDD1.

First power supply line 101 is a line for transmitting, to the constituent elements inside pixel array 11, power supply voltage VDD1 supplied from first power source 201. For this reason, although not clearly shown in FIG. 1, first power supply line 101 is present in a region that overlaps pixel array 11 in a plan view of pixel array 11.

Second power supply line 102 is a line for transmitting, to the constituent elements inside pixel array 11, power supply voltage VDD2 supplied from second power source 202. For this reason, although not clearly shown in FIG. 1, second power supply line 102 is present in a region that overlaps pixel array 11 in the plan view of pixel array 11.

Pixel 1 generates an electric charge according to the amount of received light, and outputs j (j is an integer that is greater than or equal to 2) pixel signals that are based on the amount of the electric charge generated and differ from each other in gain. In the present embodiment, the following description is based on a premise that j is 2. To put it another way, in the present embodiment, pixel 1 outputs two pixel signals of a low gain pixel signal (hereinafter the term “low conversion gain” (LCG) may be used in place of the term “low gain”) and a high gain pixel signal (hereinafter the term “high conversion gain” (HCG) may be used in place of the term “high gain”) that is a pixel signal having a gain higher than a gain of the low gain pixel signal.

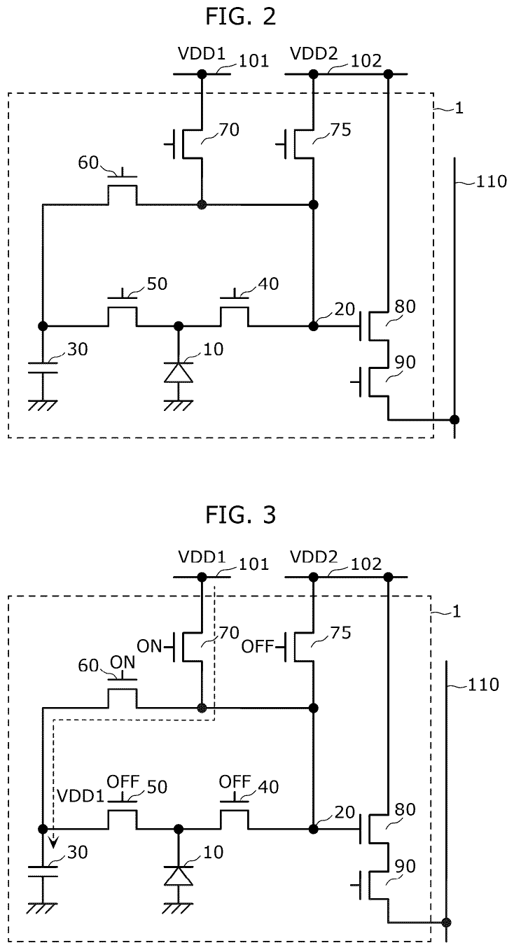

FIG. 2 is a circuit diagram illustrating the configuration of pixel 1.

As shown in FIG. 2, pixel 1 includes photoelectric converter 10, floating diffusion 20, capacitance accumulator 30, first transfer transistor 40, overflow transistor 50, second transfer transistor 60, first reset transistor 70, amplifier transistor 80, selection transistor 90, and second reset transistor 75.

It should be noted that the following description is based on a premise that pixel 1 includes overflow transistor 50, and, as stated later, overflow transistor 50 serves as a potential barrier between photoelectric converter 10 and capacitance accumulator 30. For this reason, pixel 1 need not be configured to include overflow transistor 50 as long as pixel 1 is configured to include, instead of overflow transistor 50, a constituent element that serves as a potential barrier between photoelectric converter 10 and capacitance accumulator 30.

Photoelectric converter 10 converts received light into a signal charge. In other words, photoelectric converter 10 generates a signal charge according to the amount of received light, and accumulates the signal charge generated.

Photoelectric converter 10 is achieved by, for example, a photodiode that includes a PN junction.

Hereinafter, light reception by photoelectric converter 10 is also referred to as exposure.

Floating diffusion 20 is a capacitor for accumulating a signal charge generated by photoelectric converter 10. Floating diffusion 20 changes a voltage of a signal charge by accumulating the signal charge. Stated differently, floating diffusion 20 converts a signal charge into a voltage signal.

Capacitance accumulator 30 is a capacitor for accumulating a signal charge generated by photoelectric converter 10.

Capacitance accumulator 30 is achieved by, for example, metal-insulator-metal (MIM) capacitor.

First transfer transistor 40 includes a source and a drain, one of which is connected to photoelectric converter 10 and the other of which is connected to floating diffusion 20.

First transfer transistor 40 is an NMOS transistor, and the gate of first transfer transistor 40 is driven by vertical scanning circuit 210.

When a logic level of the gate of first transfer transistor 40 becomes low, first transfer transistor 40 enters a non-conductive state; and when the logic level of the gate of first transfer transistor 40 becomes high, first transfer transistor 40 enters a conductive state.

When first transfer transistor 40 enters the conductive state, an electric charge accumulated in photoelectric converter 10 is transferred to floating diffusion 20 via first transfer transistor 40.

In other words, first transfer transistor 40 serves as a transistor for reading out a signal charge from photoelectric converter 10 to floating diffusion 20.

Overflow transistor 50 includes a source and a drain, one of which is connected to photoelectric converter 10 and the other of which is connected to capacitance accumulator 30.

Overflow transistor 50 is an NMOS transistor, and the gate of overflow transistor 50 is driven by vertical scanning circuit 210.

For this reason, it is possible to adjust the height of the potential barrier between photoelectric converter 10 and capacitance accumulator 30 by changing a voltage of the gate of overflow transistor 50.

It should be noted that although the above description is based on a premise that the gate of overflow transistor 50 is driven by vertical scanning circuit 210, the gate of overflow transistor 50 need not be configured to be driven by vertical scanning circuit 210. For example, the gate of overflow transistor 50 may be configured to be supplied with a specific voltage generated by a circuit block other than vertical scanning circuit 210.

Of the signal charge generated by photoelectric converter 10, a signal charge that has a potential exceeding the potential barrier, that is, a signal charge that overflows from photoelectric converter 10 is transferred from photoelectric converter 10 to capacitance accumulator 30.

To put it another way, overflow transistor 50 serves as a transistor for discharging, to capacitance accumulator 30, a signal charge that overflows from photoelectric converter 10.

Second transfer transistor 60 includes a source and a drain, one of which is connected to capacitance accumulator 30 and the other of which is connected to floating diffusion 20.

Second transfer transistor 60 is an NMOS transistor, and the gate of second transfer transistor 60 is driven by vertical scanning circuit 210.

When a logic level of the gate of second transfer transistor 60 becomes low, second transfer transistor 60 enters the non-conductive state; and when the logic level of the gate of second transfer transistor 60 becomes high, second transfer transistor 60 enters the conductive state.

When second transfer transistor 60 enters the conductive state, an electric charge accumulated in capacitance accumulator 30 is transferred to floating diffusion 20 via second transfer transistor 60, or an electric charge accumulated in floating diffusion 20 is transferred to capacitance accumulator 30 via second transfer transistor 60.

In other words, second transfer transistor 60 serves as a transistor for transferring a signal charge accumulated in capacitance accumulator 30 to floating diffusion 20.

Amplifier transistor 80 incudes a gate connected to floating diffusion 20, a drain connected to second power supply line 102, and a source connected to the drain of selection transistor 90 (to be described later).

Amplifier transistor 80 is an NMOS transistor. Amplifier transistor 80 and a constant current source (not shown in the figure) disposed in vertical signal line 110 to which amplifier transistor 80 is connected via selection transistor 90 (to be described later) together constitute a source follower circuit Accordingly, when selection transistor 90 (to be described later) is in the conductive state, amplifier transistor 80 outputs, to vertical signal line 110, a pixel signal according to a voltage of floating diffusion 20, that is, a signal charge generated by photoelectric converter 10.

Selection transistor 90 includes a drain connected to the source of amplifier transistor 80 and a source connected to vertical signal line 110.

Selection transistor 90 is an NMOS transistor, and the gate of selection transistor 90 is driven by vertical scanning circuit 210.

When a logic level of the gate of selection transistor 90 becomes low, selection transistor 90 enters the non-conductive state; and when the logic level of the gate of selection transistor 90 becomes high, selection transistor 90 enters the conductive state.

When selection transistor 90 enters the conductive state, a pixel outputted from amplifier transistor 80 is outputted to vertical signal line 110 via selection transistor 90. In other words, when selection transistor 90 enters the conductive state, pixel 1 enters a selection state.

First reset transistor 70 includes a source and a drain, one of which is connected to the other of the source or the drain of second transfer transistor 60 and the other of which is connected to first power supply line 101.

First reset transistor 70 is an NMOS transistor, and the gate of first reset transistor 70 is driven by vertical scanning circuit 210.

When a logic level of the gate of first reset transistor 70 becomes low, first reset transistor 70 enters the non-conductive state; and when the logic level of the gate of first reset transistor 70 becomes high, first reset transistor 70 enters the conductive state.

When first reset transistor 70 enters the conductive state, in the case where second transfer transistor 60 is in the conductive state, capacitance accumulator 30 is reset at power supply voltage VDD1.

Second reset transistor 75 includes a source and a drain, one of which is connected to the other of the source or the drain of second transfer transistor 60 and the other of which is connected to second power supply line 102.

Second reset transistor 75 is an NMOS transistor, and the gate of second reset transistor 75 is driven by vertical scanning circuit 210.

When a logic level of the gate of second reset transistor 75 becomes low, second reset transistor 75 enters the non-conductive state; and when the logic level of the gate of second reset transistor 75 becomes high, second reset transistor 75 enters the conductive state.

When second reset transistor 75 enters the conductive state, floating diffusion 20 is reset at power supply voltage VDD2.

### <Reset Operation>

Solid-state imaging device 100 thus configured resets capacitance accumulator 30 and floating diffusion 20 of each of pixels 1 by vertical scanning circuit 210 driving pixel 1.

FIG. 3 is a schematic diagram illustrating a state in which solid-state imaging device 100 resets capacitance accumulator 30.

As shown in FIG. 3, in a state in which, with regard to pixel 1 to be reset, solid-state imaging device 100 has put second transfer transistor 60 into the conductive state and put first transfer transistor 40, overflow transistor 50, and second reset transistor 75 into the non-conductive state, solid-state imaging device 100 resets capacitance accumulator 30 at power supply voltage VDD1 by switching first reset transistor 70 from the non-conductive state to the conductive state.

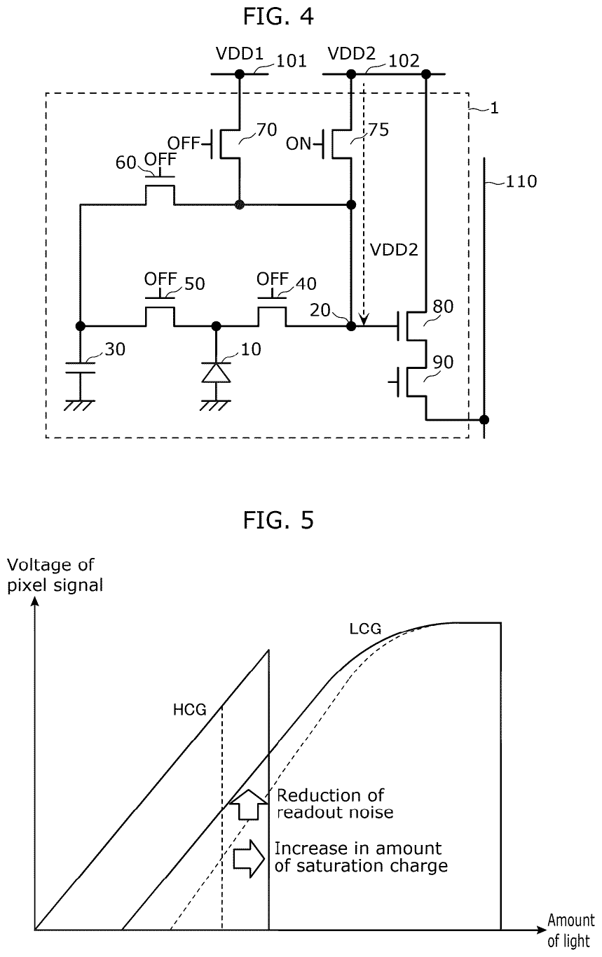

FIG. 4 is a schematic diagram illustrating a state in which solid-state imaging device 100 resets floating diffusion 20.

As shown in FIG. 4, in a state in which, with regard to pixel 1 to be reset, solid-state imaging device 100 has put first transfer transistor 40, second transfer transistor 60, overflow transistor 50, and first reset transistor 70 into the non-conductive state, solid-state imaging device 100 resets floating diffusion 20 at power supply voltage VDD2 by switching second reset transistor 75 from the non-conductive state to the conductive state.

As stated above, since solid-state imaging device 100 thus configured includes a resetter that includes second power supply line 102 and second reset transistor 75 included in each pixel 1, solid-state imaging device 100 makes it possible to reset floating diffusion 20 and capacitance accumulator 30 at the voltages different from each other in pixel 1.

### Discussion

As stated above, solid-state imaging device 100 thus configured makes it possible to reset floating diffusion 20 and capacitance accumulator 30 at the voltages different from each other.

For this reason, solid-state imaging device 100 thus configured makes it possible to both cause the voltage at which floating diffusion 20 is reset to be higher than a reliability ensuring voltage of second transfer transistor 60, and cause the voltage at which capacitance accumulator 30 is reset to be lower than or equal to a voltage obtained by subtracting a threshold voltage of second transfer transistor 60 from the reliability ensuring voltage of second transfer transistor 60. Additionally, solid-state imaging device 100 makes it possible to achieve both an increase in the amount of saturation charge and a reduction of readout noise generated when a signal charge accumulated in capacitance accumulator 30 is read out.

FIG. 5 is a graph showing a state in which solid-state imaging device 100 achieves both an increase in the amount of saturation charge and a reduction of readout noise generated when an electric charge accumulated in capacitance accumulator 30 is read out.

In FIG. 5, the vertical axis represents a voltage of a pixel signal outputted from pixel 1, and the horizontal axis represents the amount of received light of photoelectric converter 10.

As is clear from FIG. 5, solid-state imaging device 100 achieves both (i) an increase in the amount of electric charge to be read out, that is, an increase in the amount of saturation charge by resetting floating diffusion 20 at a high voltage in advance when a signal is read out from photoelectric converter 10 and (ii) a reduction of noise at the time of reading out by resetting a signal charge accumulated in capacitance accumulator 30 at a low voltage and completely discharging the accumulated signal charge by increasing a gate voltage of second transfer transistor 60 to remove a residual signal charge (residual image), that is, an improvement of a signal linearity.

### Embodiment 2

Hereinafter, a solid-state imaging device according to Embodiment 2 that is configured by partially changing the configuration of solid-state imaging device 100 according to Embodiment 1 is described.

Here, constituent elements of the solid-state imaging device according to Embodiment 2 that are common to solid-state imaging device 100 are given the same reference signs, and the detailed description thereof is omitted, as they have already been described. The following description focuses mainly on differences from solid-state imaging device 100.

### Configuration

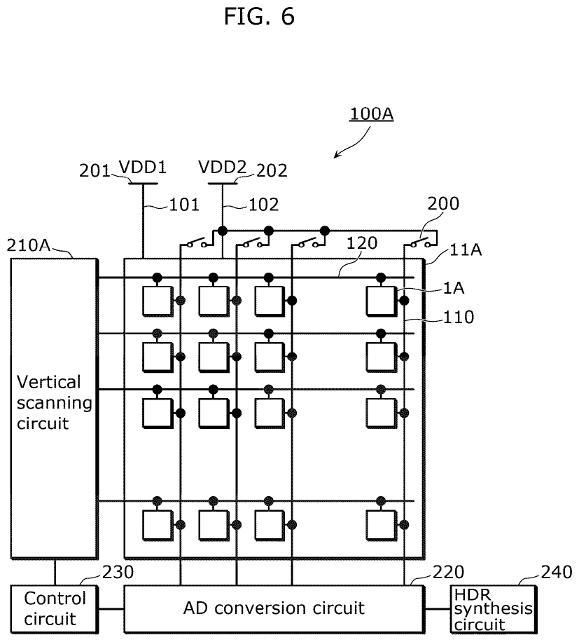

FIG. 6 is a block diagram illustrating the configuration of solid-state imaging device 100A according to Embodiment 2.

As shown in FIG. 6, solid-state imaging device 100A is configured by adding n switches 200 to solid-state imaging device 100 according to Embodiment 1 and replacing pixel array 11 and vertical scanning circuit 210 with pixel array 11A and vertical scanning circuit 210A, respectively, in solid-state imaging device 100 according to Embodiment 1.

Each of n switches 200 is a switch that is connected to second power supply line 102 and each of n vertical signal lines 110, and switches second power supply line 102 and vertical signal line 110 connected to switch 200 alternatively between the conductive state and the non-conductive state.

Here, although the following description is based on a premise that a power supply line to which switch 200 is connected is second power supply line 102, switch 200 may be configured to be connected to a power supply line other than second power supply line 102. In other words, switch 200 may be configured to be connected to a power supply line connected to a power source that supplies a power supply voltage other than power supply voltage VDD2.

Vertical scanning circuit 210A is configured by replacing a function to drive pixels 1 in vertical scanning circuit 210 according to Embodiment 1 with a function to drive pixels 1A (to be described later), and further adding a function to drive n switches 200 to vertical scanning circuit 210 according to Embodiment 1.

Pixel array 11A is configured by replacing the plurality of pixels 1 in pixel array 11 according to Embodiment 1 with a plurality of pixels 1A.

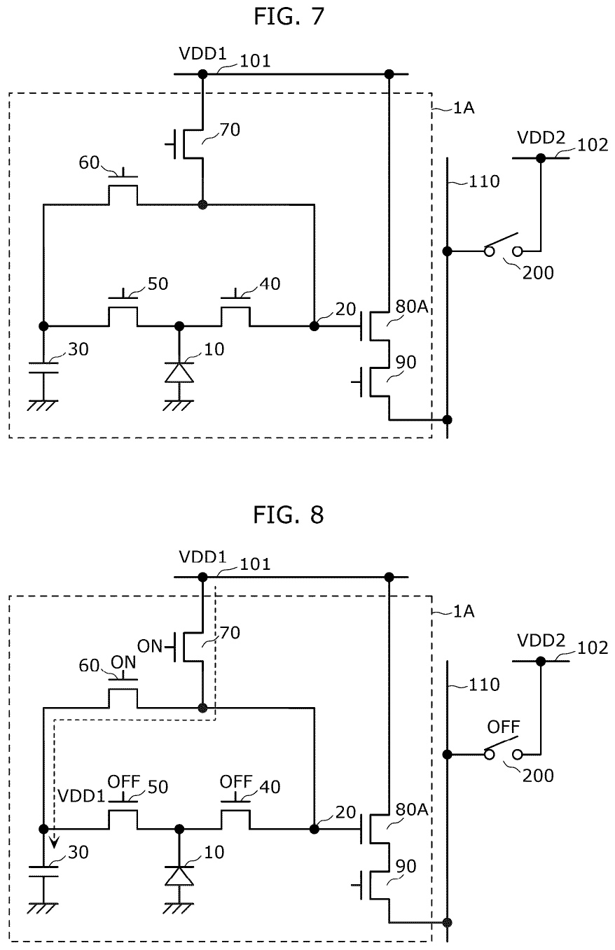

FIG. 7 is a circuit diagram illustrating the configuration of pixel 1A.

As shown in FIG. 7, pixel 1A is configured by removing second reset transistor 75 from pixel 1 according to Embodiment 1 and replacing amplifier transistor 80 with amplifier transistor 80A in pixel 1 according to Embodiment 1.

Amplifier transistor 80A is configured by changing the connection destination of the drain of amplifier transistor 80 according to Embodiment 1 from second power supply line 102 to first power supply line 101.

### <Reset Operation>

Solid-state imaging device 100A thus configured resets capacitance accumulator 30 and floating diffusion 20 of each of pixels 1A by vertical scanning circuit 210A driving pixel 1 and a corresponding one of switches 200.

FIG. 8 is a schematic diagram illustrating a state in which solid-state imaging device 100A resets capacitance accumulator 30.

As shown in FIG. 8, in a state in which, with regard to pixel 1A to be reset, solid-state imaging device 100A has put second transistor 60 into the conductive state and put overflow transistor 50 and first transfer transistor 40 into the non-conductive state, solid-state imaging device 100A resets capacitance accumulator 30 at power supply voltage VDD1 by switching first reset transistor 70 from the non-conductive state to the conductive state.

Floating diffusion 20 is reset at power supply voltage VDD1 by putting second transfer transistor 60 and first transfer transistor 40 into the non-conductive state and switching first reset transistor 70 from the non-conductive state to the conductive state. A state in which floating diffusion 20 is reset at power supply voltage VDD1 is also referred to as a temporary reset state.

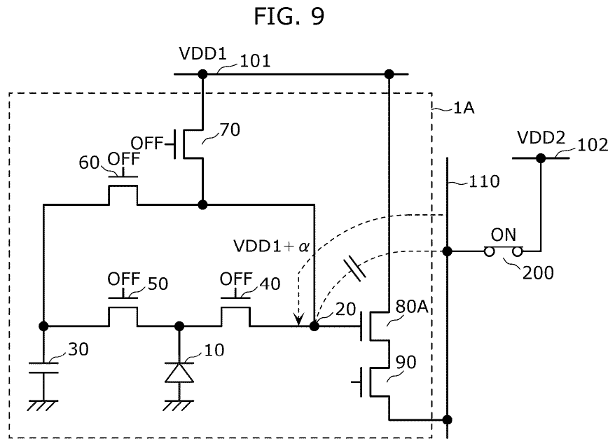

FIG. 9 is a schematic diagram illustrating a state in which solid-state imaging device 100A resets floating diffusion 20.

As shown in FIG. 9, in a state in which, with regard to pixel 1A to be reset, solid-state imaging device 100A has put first transfer transistor 40, second transfer transistor 60, overflow transistor 50, and first reset transistor 70 into the non-conductive state after putting floating diffusion 20 into the temporary reset state, solid-state imaging device 100A resets floating diffusion 20 at a voltage (i.e., VDD1+α) higher than power supply voltage VDD1 by α, by boosting a voltage of vertical signal line 110 connected to pixel 1A.

The following description is based on a premise that vertical scanning circuit 210A boosts the voltage of vertical signal line 110 connected to pixel 1A to be reset, by switching switch 200 connected to vertical signal line 110 connected to pixel 1A to be reset from the non-conductive state to the conductive state.

Parasitic capacitance is present between vertical signal line 110 connected to pixel 1A to be reset and floating diffusion 20 of pixel 1A to be reset. For this reason, when the voltage of vertical signal line 110 connected to pixel 1A to be reset is boosted, a voltage of floating diffusion 20 of pixel 1A to be reset is also boosted via the parasitic capacitance. In other words, when a voltage by which the voltage of floating diffusion 20 is boosted is denoted by α, the boosted voltage of floating diffusion 20 becomes VDD1+α.

In this manner, switch 200 serves as a voltage booster for boosting the voltage of floating diffusion 20 by a using the parasitic capacitance between floating diffusion 20 and vertical signal line 110. For this reason, switch 200 is also referred to as voltage booster 200.

Accordingly, floating diffusion 20 is reset at voltage VDD1+α.

As stated above, since solid-state imaging device 100A thus configured includes a resetter that includes n voltage boosters 200, solid-state imaging device 100A makes it possible to reset floating diffusion 20 and capacitance accumulator 30 at the voltages different from each other in each pixel 1A.

It should be noted that although the number of switches 200 included in solid-state imaging device 100A is n in Embodiment 2, the number of switches 200 included in solid-state imaging device 100A is not limited to n as long as it is possible to boost a voltage of each of n vertical signal lines 110.

Solid-state imaging device 100A may be configured to include, for example, one switch 200 that makes it possible to boost a voltage of each of n vertical signal lines 110.

### Discussion

As stated above, solid-state imaging device 100A thus configured makes it possible to reset floating diffusion 20 and capacitance accumulator 30 at the voltages different from each other.

Accordingly, as with solid-state imaging device 100 according to Embodiment 1, solid-state imaging device 100A makes it possible to achieve both an increase in the amount of saturation charge and a reduction of readout noise generated when an electric charge accumulated in capacitance accumulator 30 is read out.

### Embodiment 3

Hereinafter, a solid-state imaging device according to Embodiment 3 that is configured by partially changing the configuration of solid-state imaging device 100 according to Embodiment 1 is described.

Here, constituent elements of the solid-state imaging device according to Embodiment 3 that are common to solid-state imaging device 100 are given the same reference signs, and the detailed description thereof is omitted, as they have already been described. The following description focuses mainly on differences from solid-state imaging device 100.

### Configuration

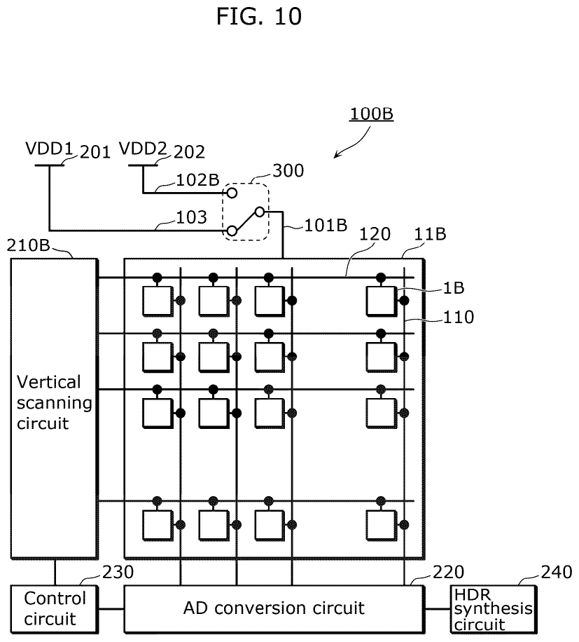

FIG. 10 is a block diagram illustrating the configuration of solid-state imaging device 100B according to Embodiment 3.

As shown in FIG. 10, solid-state imaging device 100B is configured by adding switch 300 and third power supply line 103 to solid-state imaging device 100 according to Embodiment 1 and replacing pixel array 11, vertical scanning circuit 210, first power supply line 101, and second power supply line 102 with pixel array 11B, vertical scanning circuit 210B, first power supply line 101B, and second power supply line 102B, respectively, in solid-state imaging device 100 according to Embodiment 1.

Third power supply line 103 is a line for transmitting, to switch 300, power supply voltage VDD1 supplied from first power source 201.

Second power supply line 102B is a line for transmitting, to switch 300, power supply voltage VDD2 supplied from second power source 202.

Switch 300 is a switch that switches alternatively between a state in which third power supply line 103 and first power supply line 101B are connected and a state in which second power supply line 102B and first power supply line 101B are connected. In other words, switch 300 is a switch that switches a voltage supplied to first power supply line 101B alternatively between power supply voltage VDD1 that is a first voltage and power supply voltage VDD2 that is a second voltage. For this reason, switch 300 is also referred to as voltage switch 300.

First power supply line 101B is a line for transmitting, to the constituent elements inside pixel array 11B, one of power supply voltage VDD1 or power supply voltage VDD2 alternatively switched by switch 300. For this reason, although not clearly shown in FIG. 10, first power supply line 101B is present in a region that overlaps pixel array 11B in a plan view of pixel array 11B.

Vertical scanning circuit 210B is configured by replacing a function to drive pixels 1 in vertical scanning circuit 210 according to Embodiment 1 with a function to drive pixels 1B (to be described later), and further adding a function to drive switch 300 to vertical scanning circuit 210 according to Embodiment 1.

Pixel array 11B is configured by replacing the plurality of pixels 1 in pixel array 11 according to Embodiment 1 with a plurality of pixels 1B.

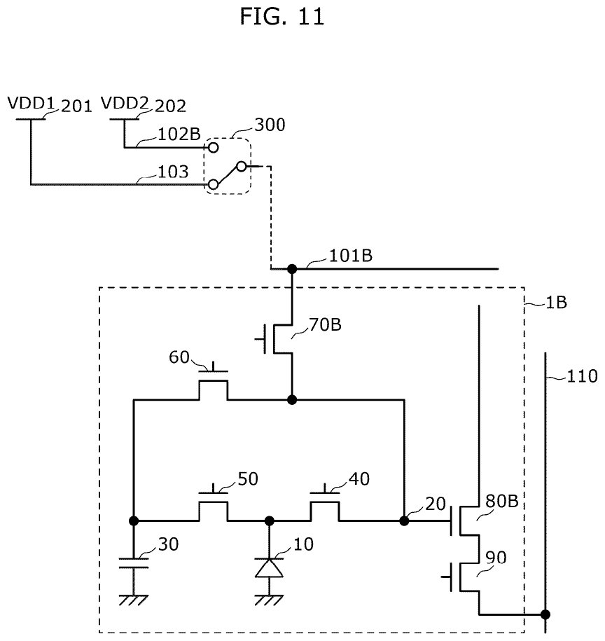

FIG. 11 is a circuit diagram illustrating the configuration of pixel 1B.

As shown in FIG. 11, pixel 1B is configured by replacing first reset transistor 70 and amplifier transistor 80A with first reset transistor 70B and amplifier transistor 80B, respectively, in pixel 1A according to Embodiment 2.

First reset transistor 70B is configured by changing the connection destination of the other of the source or the drain of first reset transistor 70 according to Embodiment 1 from first power supply line 101 to first power supply line 101B.

Amplifier transistor 80B is configured by changing the connection destination of the drain of amplifier transistor 80A according to Embodiment 1 from first power supply line 101 to a power supply line other than first power supply line 101B. The power supply line other than first power supply line 101B may be, for example, second power supply line 102B or third power supply line 103.

### <Reset Operation>

Solid-state imaging device 100B thus configured resets capacitance accumulator 30 and floating diffusion 20 of each of pixels 1B by vertical scanning circuit 210B driving pixel 1B and switch 300.

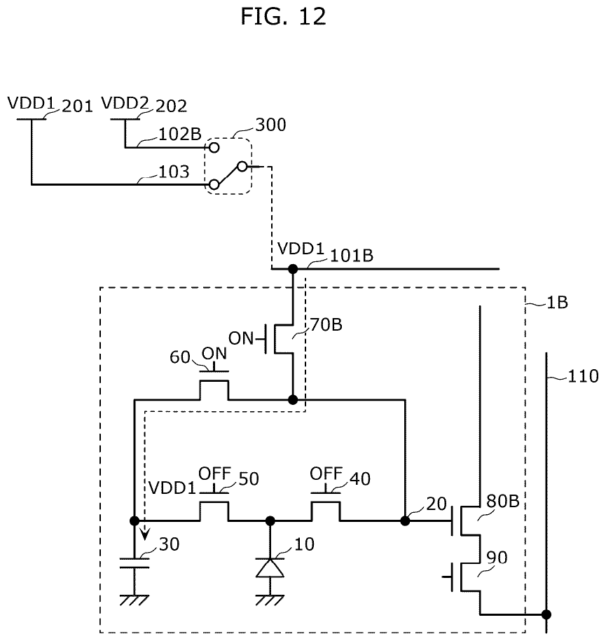

FIG. 12 is a schematic diagram illustrating a state in which solid-state imaging device 100B resets capacitance accumulator 30.

As shown in FIG. 12, in a state in which solid-state imaging device 100B has put switch 300 into the state in which third power supply line 103 and first power supply line 101B are connected, that is, solid-state imaging device 100B has set a voltage supplied to first power supply line 101B to power supply voltage VDD1, and put, with regard to pixel 1B to be reset, second transfer transistor 60 into the conductive state and first transfer transistor 40 and overflow transistor 50 into the non-conductive state, solid-state imaging device 100B resets capacitance accumulator 30 at power supply voltage VDD1 by switching first reset transistor 70B from the non-conductive state to the conductive state.

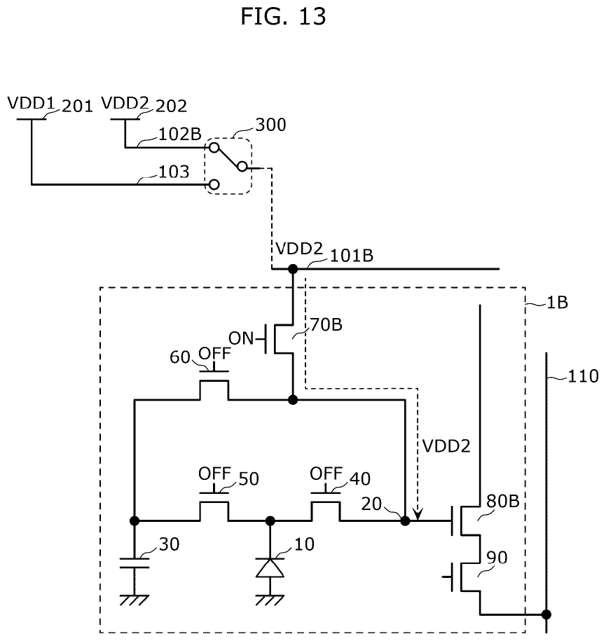

FIG. 13 is a schematic diagram illustrating a state in which solid-state imaging device 100B resets floating diffusion 20.

As shown in FIG. 13, in a state in which solid-state imaging device 100B has put switch 300 into the state in which second power supply line 102B and first power supply line 101B are connected, that is, solid-state imaging device 100B has set a voltage supplied to first power supply line 101B to power supply voltage VDD2, and put, with regard to pixel 1B to be reset, first transfer transistor 40, second transfer transistor 60, and overflow transistor 50 into the non-conductive state, solid-state imaging device 100B resets floating diffusion 20 at power supply voltage VDD2 by switching first reset transistor 70B from the non-conductive state to the conductive state.

As stated above, since solid-state imaging device 100B thus configured includes a resetter that includes voltage switch 300, solid-state imaging device 100B makes it possible to reset floating diffusion 20 and capacitance accumulator 30 at the voltages different from each other in each pixel 1B.

### Discussion

As stated above, solid-state imaging device 100B thus configured makes it possible to reset floating diffusion 20 and capacitance accumulator 30 at the voltages different from each other.

Accordingly, as with solid-state imaging device 100 according to Embodiment 1, solid-state imaging device 100B makes it possible to achieve both an increase in the amount of saturation charge and a reduction of readout noise generated when an electric charge accumulated in capacitance accumulator 30 is read out.

### Embodiment 4

Hereinafter, a solid-state imaging device according to Embodiment 4 that is configured by partially changing the configuration of solid-state imaging device 100 according to Embodiment 1 is described.

Here, constituent elements of the solid-state imaging device according to Embodiment 4 that are common to solid-state imaging device 100 are given the same reference signs, and the detailed description thereof is omitted, as they have already been described. The following description focuses mainly on differences from solid-state imaging device 100.

### Configuration

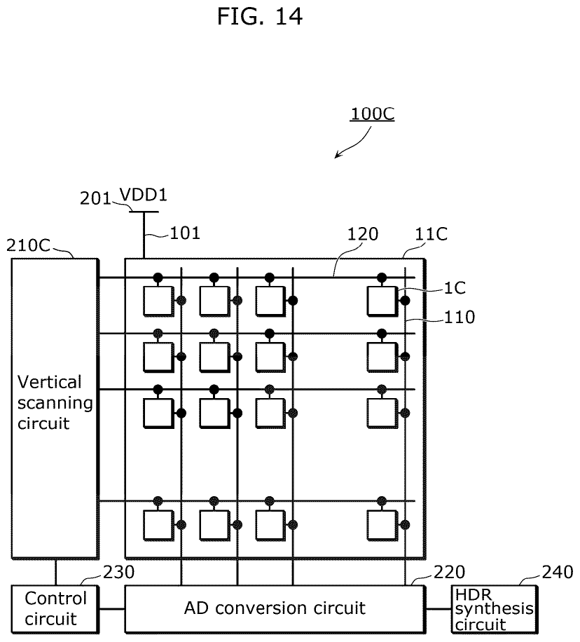

FIG. 14 is a block diagram illustrating the configuration of solid-state imaging device 100C according to Embodiment 4.

As shown in FIG. 14, solid-state imaging device 100C is configured by removing second power source 202 and second power supply line 102 from solid-state imaging device 100 according to Embodiment 1, and replacing pixel array 11 and vertical scanning circuit 210 with pixel array 11C and vertical scanning circuit 210C, respectively, in solid-state imaging device 100 according to Embodiment 1.

Vertical scanning circuit 210C is configured by replacing a function to drive pixels 1 in vertical scanning circuit 210 according to Embodiment 1 with a function to drive pixels 1C (to be described later).

Pixel array 11C is configured by replacing the plurality of pixels 1 in pixel array 11 according to Embodiment 1 with a plurality of pixels 1C.

In Embodiment 1 to Embodiment 3, pixel 1, pixel 1A, and pixel 1B each show an example of the configuration in which the two pixel signals having the gains different from each other are outputted. In other words, pixel 1, pixel 1A, and pixel 1B each show an example of the configuration in which j is 2.

In contrast, pixel 1C shows an example of a configuration in which three pixel signals having gains different from each other are outputted. In other words, pixel 1C shows an example of a configuration in which j is 3.

Here, pixel 1C outputs three pixel signals of a low gain (LCG) pixel signal, a high gain (HCG) pixel signal, and a medium gain pixel signal (hereinafter the term “medium conversion gain” (MCG) may be used in place of the term “medium gain”) that is a pixel signal having a gain higher than a gain of the low gain pixel signal and lower than a gain of the high gain pixel signal.

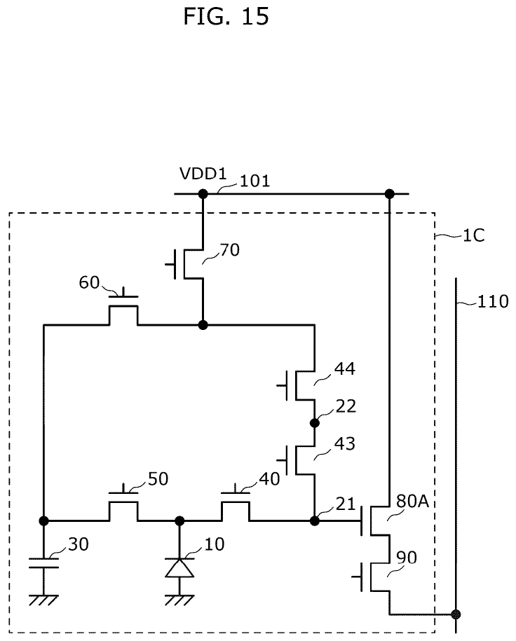

FIG. 15 is a circuit diagram illustrating the configuration of pixel 1C.

As shown in FIG. 15, pixel 1C is configured by removing second reset transistor 75 from pixel 1 according to Embodiment 1, replacing floating diffusion 20 and amplifier transistor 80 with first floating diffusion 21 and amplifier transistor 80A, respectively, in pixel 1 according to Embodiment 1, and adding second floating diffusion 22, third transfer transistor 43, and fourth transfer transistor 44 to pixel 1 according to Embodiment 1.

Due to the replacement, the connection destination of the other of the source or the drain of first transfer transistor 40 is changed from floating diffusion 20 to first floating diffusion 21.

Second floating diffusion 22 is a capacitor for accumulating a signal charge generated by photoelectric converter 10.

Third transfer transistor 43 includes a source and a drain, one of which is connected to first floating diffusion 21 and the other of which is connected to second floating diffusion 22.

Third transfer transistor 43 is an NMOS transistor, and the gate of third transfer transistor 43 is driven by vertical scanning circuit 210C.

When a logic level of the gate of third transfer transistor 43 becomes low, third transfer transistor 43 enters the non-conductive state; and when the logic level of the gate of third transfer transistor 43 becomes high, third transfer transistor 43 enters the conductive state.

When third transfer transistor 43 enters the conductive state, an electric charge accumulated in first floating diffusion 21 is transferred to second floating diffusion 22 via third transfer transistor 43, or an electric charge accumulated in second floating diffusion 22 is transferred to first floating diffusion 21 via third transfer transistor 43.

Fourth transfer transistor 44 includes a source and a drain, one of which is connected to second floating diffusion 22 and the other of which is connected to the other of the source or the drain of first reset transistor 70.

Fourth transfer transistor 44 is an NMOS transistor, and the gate of fourth transfer transistor 44 is driven by vertical scanning circuit 210C.

When a logic level of the gate of fourth transfer transistor 44 becomes low, fourth transfer transistor 44 enters the non-conductive state; and when the logic level of the gate of fourth transfer transistor 44 becomes high, fourth transfer transistor 44 enters the conductive state.

When fourth transfer transistor 44 enters the conductive state, an electric charge accumulated in second floating diffusion 22 is transferred to the one of the source or the drain of first reset transistor 70 via fourth transfer transistor 44, or an electric charge accumulated in the one of the source or the drain of first reset transistor 70 is transferred to second floating diffusion 22 via fourth transfer transistor 44.

In pixel 1C thus configured, first transfer transistor 40 serves as a transistor for reading out a signal charge from photoelectric converter 10 to first floating diffusion 21, and second transfer transistor 60 serves as a transistor for transferring a signal charge accumulated in capacitance accumulator 30 to second floating diffusion 22.

### <Signal Charge Accumulation Operation>

Solid-state imaging device 100C thus configured transfers a signal charge from photoelectric converter 10 of each of pixels 1C to first floating diffusion 21 and second floating diffusion 22 by vertical scanning circuit 210C driving pixel 1C.

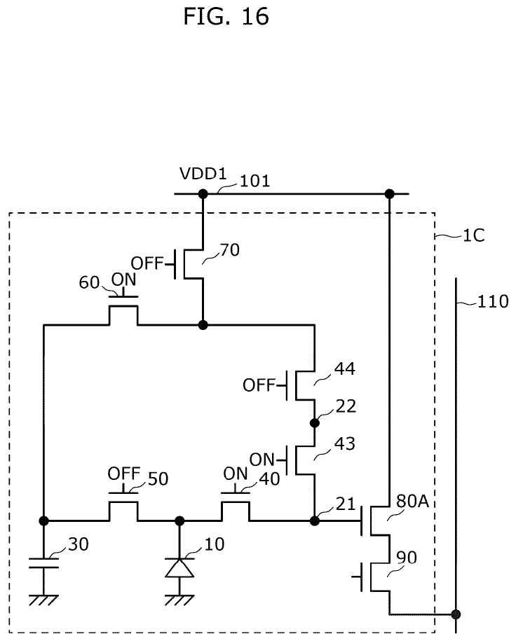

FIG. 16 is a schematic diagram illustrating a state in which solid-state imaging device 100C transfers a signal charge from photoelectric converter 10 to first floating diffusion 21 and second floating diffusion 22.

As shown in FIG. 16, with regard to pixel 1C for which a signal charge is transferred from photoelectric converter 10 to first floating diffusion 21 and second floating diffusion 22, by putting first transfer transistor 40, second transfer transistor 60, and third transfer transistor 43 into the conductive state, and putting first reset transistor 70, overflow transistor 50, and fourth transfer transistor 44 into the non-conductive state, solid-state imaging device 100C transfers the signal charge from photoelectric converter 10 to first floating diffusion 21 and second floating diffusion 22.

In transferring a signal charge from photoelectric converter 10 to first floating diffusion 21 and second floating diffusion 22, when a signal charge generated by photoelectric converter 10 exceeds a fixed amount, the signal charge that cannot be accumulated in first floating diffusion 21 and second floating diffusion 22 may overflow toward first reset transistor 70 across a potential barrier of fourth transfer transistor 44 in the non-conductive state.

In this case, since first reset transistor 70 is in the non-conductive state and second transfer transistor 60 is in the conductive state, the overflowing signal charge is accumulated in capacitance accumulator 30 without flowing to first power supply line 101.

### Discussion

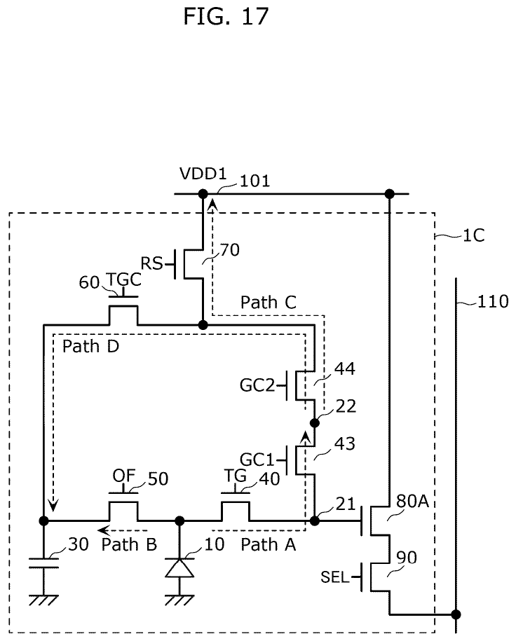

FIG. 17 is a schematic diagram illustrating a state in which each of the transistors included in pixel 1C is driven by a corresponding one of control signals outputted from vertical scanning circuit 210C.

As shown in FIG. 17, in pixel 1C, first transfer transistor 40 is driven by control signal TG, overflow transistor 50 is driven by control signal OF, second transfer transistor 60 is driven by control signal TGC, first reset transistor 70 is driven by control signal RS, third transfer transistor 43 is driven by control signal GC1, fourth transfer transistor 44 is driven by control signal GC2, and selection transistor 90 is driven by control signal SEL.

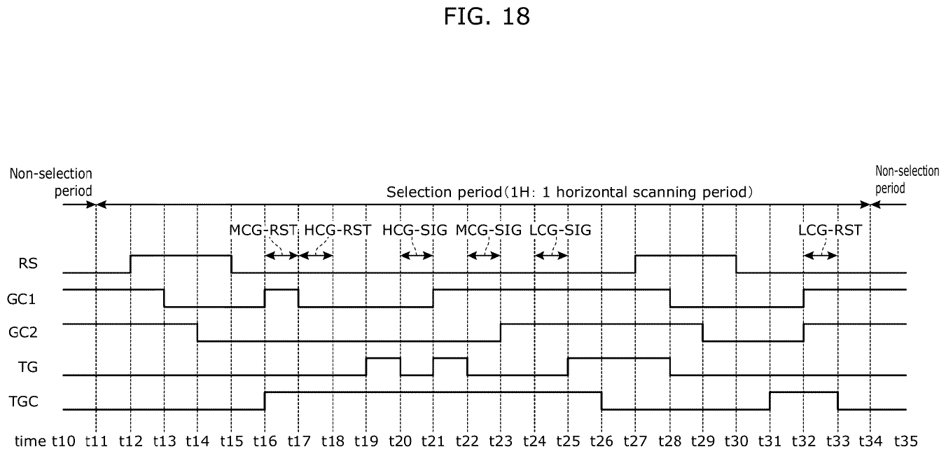

FIG. 18 is an example of a timing chart for control signals used when vertical scanning circuit 210C drives one or more pixels 1C in one horizontal scanning period that is a selection period in which vertical scanning circuit 210C selects one or more pixels 1C arranged in one row in pixel array 11C.

In FIG. 18, the horizontal axis represents time, and the vertical axis represents a logic value of each of the control signals.

As shown in FIG. 18, first, vertical scanning circuit 210C puts fourth transfer transistor 44 into the non-conductive state by causing a logic level of control signal GC2 to be low at time t14. Next, vertical scanning circuit 210C puts first reset transistor 70 into the non-conductive state by causing a logic level of control signal RS to be low at time t15. Then, vertical scanning circuit 210C puts second transfer transistor 60 into the conductive state by causing a logic level of control signal TGC at time t16. After that, vertical scanning circuit 210C puts first transfer transistor 40 into the conductive state by causing a logic level of control signal TG to be high in a period between time t19 and t20.

Accordingly, a signal charge of photoelectric converter 10 is transferred to first floating diffusion 21 in the period between time t19 and t20. Next, an HCG pixel signal corresponding to the signal charge transferred to first floating diffusion 21 is read out from vertical signal line 110 in a period between time t20 and t21.

Then, vertical scanning circuit 210C puts first transfer transistor 40 and third transfer transistor 43 into the conductive state by causing logic levels of control signal TG and control signal GC1 to be high in a period between time t21 and t22.

Accordingly, the signal charge of photoelectric converter 10 and first floating diffusion 21 is distributed to first floating diffusion 21 and second floating diffusion 22 in the period between time t21 and t22. After that, an MCG pixel signal corresponding to the signal charge distributed to first floating diffusion 21 and second floating diffusion 22 is read out from vertical signal line 110 in a period between time t22 and t23.

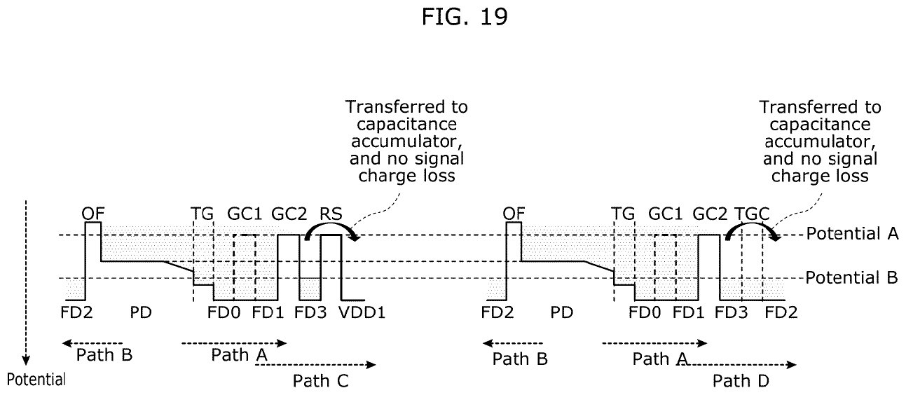

FIG. 19 is a schematic diagram illustrating a potential of each of photoelectric converter 10 (PD shown in FIG. 19), first floating diffusion 21 (FD0 shown in FIG. 19), second floating diffusion 22 (FD1 shown in FIG. 19), one of the source or the drain of first reset transistor 70 (FD3 shown in FIG. 19), and capacitance accumulator 30 (FD2 shown in FIG. 19) in the period between time t21 and t22 shown in FIG. 18.

In FIG. 19, the vertical axis represents a potential.

Path A, path B, path C, and path D shown in FIG. 19 correspond to path A, path B, path C, and path D shown in FIG. 17, respectively.

As shown in FIG. 19, in path C, a potential barrier of first reset transistor 70 in the non-conductive state is present between the one of the source or the drain of first reset transistor 70 (FD3) and first power supply line 101 (VDD1). In contrast, in path D, a potential barrier is not present between the one of the source or the drain of first reset transistor 70 (FD3) and capacitance accumulator 30 (FD2).

For this reason, a signal charge that overflows from second floating diffusion 22 toward first reset transistor 70 across the potential barrier of fourth transfer transistor 44 in the non-conductive state is accumulated in capacitance accumulator 30 without flowing to first power supply line 101 across the potential barrier of first reset transistor 70 in the non-conductive state in path C.

It should be noted that, as shown in FIG. 18, the control signals in the period between t19 and t20 are the same as the control signals in the period between t21 and t22, except that the logic level of control signal GC1 is low in the period between time t19 and t20 whereas the logic level of control signal GC1 is high in the period between time t21 and t22.

For this reason, in FIG. 19, a state in which the logic level of control signal GC1 becomes low as shown by the broken line indicates the potentials of photoelectric converter 10, first floating diffusion 21, second floating diffusion 22, the one of the source or the drain of first reset transistor 70, and capacitance accumulator 30 in the period between time t19 and t20 shown in FIG. 18.

Accordingly, of a signal charge that overflows from first floating diffusion 21 to second floating diffusion 22 across the potential barrier of third transfer transistor 43 in the non-conductive state, a signal charge that further overflows from second floating diffusion 22 toward first reset transistor 70 across the potential barrier of fourth transfer transistor 44 in the non-conductive state is accumulated in capacitance accumulator 30 without flowing to first power supply line 101, as with the case in the period between time t21 and t22.

As stated above, even when the amount of saturation charge of photoelectric converter 10 is increased, solid-state imaging device 100C thus configured makes it possible to reduce the outflow of the signal charge generated by photoelectric converter 10 to the outside of each of pixels 1C and improve a signal linearity by, with regard to pixel 1C, vertical scanning circuit 210C putting fourth transfer transistor 44 and first reset transistor 70 into the non-conductive state and second transfer transistor 60 into the conductive state per row in pixel array 11C.

Moreover, solid-state imaging device 100C thus configured makes it possible to accumulate the signal charge overflowing from first floating diffusion 21 and second floating diffusion 22 in capacitance accumulator 30 by, with regard to each of pixels 1C, vertical scanning circuit 210C putting fourth transfer transistor 44 and first reset transistor 70 into the non-conductive state and second transfer transistor 60 into the conductive state per row in pixel array 11C.

Accordingly, solid-state imaging device 100C thus configured makes it possible to achieve an increase in the amount of saturation charge and a reduction of readout noise generated when the signal charge accumulated in capacitance accumulator 30 is read out.

It should be noted that although, in Embodiment 4, pixel 1C is configured by removing second reset transistor 75 from pixel 1 according to Embodiment 1, pixel 1C need not be configured by removing second reset transistor 75 from pixel 1. Pixel 1C may be configured by, for example, replacing floating diffusion 20 with first floating diffusion 21 in pixel 1 according to Embodiment 1, and adding second floating diffusion 22, third transfer transistor 43, and fourth transfer transistor 44 to pixel 1 according to Embodiment 1.

It should be noted that although, in Embodiment 4, solid-state imaging device 100C is configured by removing second reset transistor 75 from pixel 1 of solid-state imaging device 100 according to Embodiment 1, replacing floating diffusion 20 and amplifier transistor 80 with first floating diffusion 21 and amplifier transistor 80A, respectively, in pixel 1 of solid-state imaging device 100 according to Embodiment 1, and adding second floating diffusion 22, third transfer transistor 43, and fourth transfer transistor 44 to pixel 1 of solid-state imaging device 100 according to Embodiment 1, solid-state imaging device 100C need not be limited to the above configuration. Solid-state imaging device 100C may be configured by, for example, replacing floating diffusion 20 with first floating diffusion 21 in pixel 1A of solid-state imaging device 100A according to Embodiment 2, and adding second floating diffusion 22, third transfer transistor 43, and fourth transfer transistor 44 to pixel 1A of solid-state imaging device 100A according to Embodiment 2. Alternatively, solid-state imaging device 100C may be configured by, for example, replacing floating diffusion 20 with first floating diffusion 21 in pixel 1B of solid-state imaging device 100B according to Embodiment 3, and adding second floating diffusion 22, third transfer transistor 43, and fourth transfer transistor 44 to pixel 1B of solid-state imaging device 100B according to Embodiment 3.

### Embodiment 5

Hereinafter, an imaging apparatus according to Embodiment 5 that includes the solid-state imaging device according to any one of Embodiment 1 to Embodiment 4 is described.

The following description is based on a premise that the imaging apparatus according to Embodiment 5 includes solid-state imaging device 100 according to Embodiment 1. However, the imaging apparatus according to Embodiment 5 need not include solid-state imaging device 100 according to Embodiment 1 as long as the imaging apparatus according to Embodiment 5 includes the solid-state imaging device according to any one of Embodiment 1 to Embodiment 4.

### Configuration

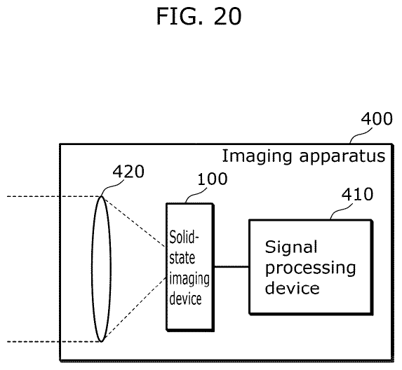

FIG. 20 is a block diagram illustrating the configuration of imaging apparatus 400 according to Embodiment 5.

Imaging apparatus 400 is, for example, a digital still camera or a handy video recorder.

As shown in FIG. 20, imaging apparatus 400 includes solid-state imaging device 100, signal processing device 410, and lens 420.

Lens 420 focuses light from a subject that is a target captured by imaging apparatus 400 on a region in which pixel array 11 is provided in solid-state imaging device 100, and forms an image of the subject in the region in which pixel array 11 is provided in solid-state imaging device 100.

Signal processing device 410 performs various types of signal processing on a signal (e.g., an image) outputted from solid-state imaging device 100.

### Discussion

As stated in Embodiment 1 to Embodiment 4, solid-state imaging device 100, solid-state imaging device 100A, solid-state imaging device 100B, and solid-state imaging device 100C make it possible to achieve both an increase in the amount of saturation charge and a reduction of readout noise generated when the signal charge accumulated in capacitance accumulator 30 is read out.

Accordingly, imaging apparatus 400 thus configured makes it possible to achieve both an increase in the amount of saturation charge and a reduction of readout noise generated when the signal charge accumulated in capacitance accumulator 30 is read out, and achieve a wider HDR.

### Supplement

Embodiment 1 to Embodiment 5 are described above as examples of the techniques disclosed in the Specification. However, the present disclosure is not limited to these embodiments. Forms obtained by various modifications to each of the embodiments that can be conceived by a person skilled in the art or forms realized by combining the constituent elements in different embodiments or variations may be included in the scope of one or more aspects of the present disclosure, as long as they do not depart from the gist of the present disclosure.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The present disclosure is widely applicable to, for example, solid-state imaging devices that capture images.

1. A solid-state imaging device comprising:
a pixel array in which a plurality of pixels are arranged in rows and columns; and
a first power supply line,
wherein each of the plurality of pixels includes:
a photoelectric converter that converts received light into a signal charge;
a floating diffusion for accumulating the signal charge;
a capacitance accumulator for accumulating the signal charge;
a first transfer transistor for reading out the signal charge from the photoelectric converter to the floating diffusion;
an overflow transistor for discharging, to the capacitance accumulator, the signal charge that overflows from the photoelectric converter;
a second transfer transistor for transferring the signal charge accumulated in the capacitance accumulator to the floating diffusion;
a first reset transistor that includes a first terminal connected to the second transfer transistor and a second terminal connected to the first power supply line; and
an amplifier transistor that includes a gate connected to the floating diffusion,
the solid-state imaging device further comprises a resetter for resetting the floating diffusion and the capacitance accumulator at voltages different from each other.

2. The solid-state imaging device according to claim 1,
wherein the resetter includes: a second power supply line that is included in the solid-state imaging device; and a second reset transistor that is included in each of the plurality of pixels and includes a third terminal connected to the second transfer transistor and a fourth terminal connected to the second power supply line.

3. The solid-state imaging device according to claim 2,
wherein a first voltage of the first power supply line is lower than a second voltage of the second power supply line.

4. The solid-state imaging device according to claim 3,
wherein a voltage at which the capacitance accumulator is reset is the first voltage, and a voltage at which the floating diffusion is reset is the second voltage.

5. The solid-state imaging device according to claim 1,
wherein the resetter includes a voltage booster for boosting a voltage of the floating diffusion, the voltage booster being included in the solid-state imaging device.

6. The solid-state imaging device according to claim 1,
wherein the resetter includes a voltage switch that switches a voltage of the first power supply line alternatively between a first voltage and a second voltage different from the first voltage, the voltage switch being included in the solid-state imaging device.

7. The solid-state imaging device according to claim 6,
wherein the first voltage of the first power supply line is lower than the second voltage.

8. The solid-state imaging device according to claim 7,
wherein a voltage at which the capacitance accumulator is reset is the first voltage, and a voltage at which the floating diffusion is reset is the second voltage.

9. A solid-state imaging device comprising:
a pixel array in which a plurality of pixels are arranged in rows and columns; and
a power supply line,
wherein each of the plurality of pixels includes:
a photoelectric converter that converts received light into a signal charge;
a first floating diffusion for accumulating the signal charge;
a second floating diffusion for accumulating the signal charge;
a capacitance accumulator for accumulating the signal charge;
a first transfer transistor for reading out the signal charge from the photoelectric converter to the first floating diffusion;
an overflow transistor for discharging, to the capacitance accumulator, the signal charge that overflows from the photoelectric converter;
a second transfer transistor for transferring the signal charge accumulated in the capacitance accumulator to the second floating diffusion;
a reset transistor that includes a first terminal connected to the second transfer transistor and a second terminal connected to the power supply line;
a third transfer transistor that includes a third terminal connected to the first floating diffusion and a fourth terminal connected to the second floating diffusion;
a fourth transfer transistor that includes a fifth terminal connected to the second floating diffusion and a sixth terminal connected to the reset transistor; and
an amplifier transistor that includes a gate connected to the first floating diffusion,
the solid-state imaging device further comprises a vertical scanning circuit that puts the fourth transfer transistor of each of the plurality of pixels into a non-conductive state, the reset transistor of the pixel into the non-conductive state, and the second transfer transistor of the pixel into a conductive state.

10. An imaging apparatus comprising the solid-state imaging device according to claim 1.
